(19) United States
(12) Patent Application Publication
(10) Pub. No.: US 2026/0164888 A1
(43) Pub. Date: Jun. 11, 2026

(54) Display Device Including Light Emitting Diode

(71) Applicant: LG Display Co., Ltd., Seoul (KR)

(72) Inventor: Min-Jae Kang, Paju-si (KR)

(21) Appl. No.: 19/308,984

(22) Filed: Aug. 25, 2025

(30) Foreign Application Priority Data
Dec. 10, 2024 (KR) 10-2024-0182134

(51) Int. Cl. H10H 29/49; H10H 29/34

(52) U.S. Cl. CPC H10H 29/49; H10H 29/34

(57) ABSTRACT

A display device includes: a display panel; a plurality of gate lines and a plurality of data lines in the display panel, the plurality of gate lines and the plurality of data lines crossing each other to define first, second and third subpixels; a transistor in each of the first, second and third subpixels and connected to the plurality of gate lines and the plurality of data lines; and first, second and third light emitting diodes in the first, second and third subpixels, respectively, and connected to the transistor, wherein the first light emitting diode includes a first short wavelength light emitting diode and a first long wavelength light emitting diode having shapes different from each other to have an exclusivity, and wherein the first short wavelength light emitting diode and the first long wavelength light emitting diode are alternately disposed along a horizontal direction and a vertical direction.

### CROSS-REFERENCE TO RELATED APPLICATION

The present application claims the priority of Republic of Korea Patent Application No. 10-2024-0182134 filed on Dec. 10, 2024, which is hereby incorporated by reference in its entirety.

### BACKGROUND

### Field of the Disclosure

The present disclosure relates to a display device, and more particularly, to a display device including a light emitting diode of a short wavelength and a long wavelength.

### Description of the Background

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to moisture and oxygen.

To overcome the disadvantage, a display device using a light emitting diode chip (or a light emitting diode) of an inorganic material has been suggested.

The light emitting diode chip is attached to a display panel after the light emitting diode chip is formed on a growth substrate. To distinguish red, green and blue light emitting diode chips from each other, the red, green and blue light emitting diode chips are formed to have elliptical shapes having different long axes and different short axes.

The light emitting diode chip may be formed using a plurality of epitaxial wafers where gallium nitride (GaN) is formed through a growth of crystal on a plurality of sapphire wafers. Although most of the plurality of epitaxial wafers may have a dominant wavelength (Wd) of a middle wavelength corresponding to a target wavelength, some of the plurality of epitaxial wafers may have the dominant wavelength of a short wavelength shorter than the target wavelength or the dominant wavelength of a long wavelength longer than the target wavelength.

As a result, a light emitting diode chip of a short wavelength, a light emitting diode chip of a long wavelength and a light emitting diode chip of a middle wavelength are fabricated from the plurality of epitaxial wafers. When the light emitting diode chips of a short wavelength and a long wavelength are used for a display device together with the light emitting diode chip of a middle wavelength, the domain wavelengths of the plurality of light emitting diode chips have a great difference. Accordingly, a color deviation occurs between regions where the plurality of light emitting diode chips of each of the short, long and middle wavelengths are disposed.

When only the light emitting diode chip of a middle wavelength among the plurality of light emitting diode chips fabricated from the plurality epitaxial wafers is used for a display device to prevent the color deviation, a usage yield of the light emitting diode chip is reduced and a fabrication cost of a display device increases.

### SUMMARY

Accordingly, the present disclosure is directed to a display device that substantially obviates one or more of the problems due to limitations and disadvantages of the related art.

More specifically, the present disclosure is to provide a display device including a light emitting diode where a color mixture is prevented or at least reduced and a fabrication process is optimized by forming the light emitting diodes of short and long wavelengths as an asymmetric polygonal shape.

Further, the present disclosure is to provide a display device including a light emitting diode where a usage yield of a chip increases and a fabrication cost is reduced by forming the light emitting diodes of short and long wavelengths as an asymmetric polygonal shape and a linear shape having an area corresponding to the light emitting diode of a middle wavelength.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel; a plurality of gate lines and a plurality of data lines in the display panel, the plurality of gate lines and the plurality of data lines crossing each other to define first, second and third subpixels; a transistor in each of the first, second and third subpixels and connected to the plurality of gate lines and the plurality of data lines; and first, second and third light emitting diodes in the first, second and third subpixels, respectively, and connected to the transistor, wherein the first light emitting diode includes a first short wavelength light emitting diode and a first long wavelength light emitting diode having shapes different from each other to have an exclusivity, and wherein the first short wavelength light emitting diode and the first long wavelength light emitting diode are alternately disposed along a horizontal direction and a vertical direction.

In another embodiment, a light emitting diode includes: a first semiconductor layer; an active layer on the first semiconductor layer; and a second semiconductor layer on the active layer, wherein the first semiconductor layer has a bottom pattern of one of an embossed shape and an engraved shape.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a circuit diagram showing a subpixel of a display device according to a first embodiment of the present disclosure;

FIG. 3 is a cross-sectional view showing a subpixel of a display panel of a display device according to a first embodiment of the present disclosure;

FIG. 4 is a view showing an assembly substrate of a light emitting diode of a display device according to a first embodiment of the present disclosure;

FIG. 5 is a magnified view of a portion A of FIG. 4 according to one embodiment of the present disclosure;

FIG. 6 is a view showing a display panel of a display device according to a first embodiment of the present disclosure;

FIG. 7A is a view showing a first short wavelength assembly groove of an assembly substrate and a first short wavelength light emitting diode for a display device according to a first embodiment of the present disclosure;

FIG. 7B is a view showing a first short wavelength assembly groove of an assembly substrate and a first long wavelength light emitting diode for a display device according to a first embodiment of the present disclosure;

FIG. 7C is a view showing a first short wavelength assembly groove of an assembly substrate and a second light emitting diode for a display device according to a first embodiment of the present disclosure;

FIG. 7D is a view showing a first short wavelength assembly groove of an assembly substrate and a third light emitting diode for a display device according to a first embodiment of the present disclosure;

FIG. 8A is a view showing a first long wavelength assembly groove of an assembly substrate and a first long wavelength light emitting diode for a display device according to a first embodiment of the present disclosure;

FIG. 8B is a view showing a first long wavelength assembly groove of an assembly substrate and a first short wavelength light emitting diode for a display device according to a first embodiment of the present disclosure;

FIG. 8C is a view showing a first long wavelength assembly groove of an assembly substrate and a second light emitting diode for a display device according to a first embodiment of the present disclosure;

FIG. 8D is a view showing a first long wavelength assembly groove of an assembly substrate and a third light emitting diode for a display device according to a first embodiment of the present disclosure;

FIG. 9 is a view showing a second assembly groove of an assembly substrate and a second light emitting diode for a display device according to a first embodiment of the present disclosure;

FIG. 10 is a view showing a third assembly groove of an assembly substrate and a third light emitting diode for a display device according to a first embodiment of the present disclosure;

FIG. 11 is a view showing a plurality of epitaxial wavers for a light emitting diode of a display device according to a first embodiment of the present disclosure;

FIG. 12 is a view showing a display panel of a display device according to a second embodiment of the present disclosure;

FIG. 13A is a view showing a first short wavelength assembly groove of an assembly substrate and a first short wavelength light emitting diode for a display device according to a second embodiment of the present disclosure;

FIG. 13B is a view showing a first short wavelength assembly groove of an assembly substrate and a first long wavelength light emitting diode for a display device according to a second embodiment of the present disclosure;

FIG. 13C is a view showing a first short wavelength assembly groove of an assembly substrate and a first middle wavelength light emitting diode for a display device according to a second embodiment of the present disclosure;

FIG. 13D is a view showing a first short wavelength assembly groove of an assembly substrate and a second light emitting diode for a display device according to a second embodiment of the present disclosure;

FIG. 13E is a view showing a first short wavelength assembly groove of an assembly substrate and a third light emitting diode for a display device according to a second embodiment of the present disclosure;

FIG. 14A is a view showing a first long wavelength assembly groove of an assembly substrate and a first long wavelength light emitting diode for a display device according to a second embodiment of the present disclosure;

FIG. 14B is a view showing a first long wavelength assembly groove of an assembly substrate and a first short wavelength light emitting diode for a display device according to a second embodiment of the present disclosure;

FIG. 14C is a view showing a first long wavelength assembly groove of an assembly substrate and a first middle wavelength light emitting diode for a display device according to a second embodiment of the present disclosure;

FIG. 14D is a view showing a first long wavelength assembly groove of an assembly substrate and a second light emitting diode for a display device according to a second embodiment of the present disclosure;

FIG. 14E is a view showing a first long wavelength assembly groove of an assembly substrate and a third light emitting diode for a display device according to a second embodiment of the present disclosure;

FIG. 15A is a view showing a first middle wavelength assembly groove of an assembly substrate and a first middle wavelength light emitting diode for a display device according to a second embodiment of the present disclosure;

FIG. 15B is a view showing a first middle wavelength assembly groove of an assembly substrate and a first short wavelength light emitting diode for a display device according to a second embodiment of the present disclosure;

FIG. 15C is a view showing a first middle wavelength assembly groove of an assembly substrate and a first long wavelength light emitting diode for a display device according to a second embodiment of the present disclosure;

FIG. 15D is a view showing a first middle wavelength assembly groove of an assembly substrate and a second light emitting diode for a display device according to a second embodiment of the present disclosure; and

FIG. 15E is a view showing a first middle wavelength assembly groove of an assembly substrate and a third light emitting diode for a display device according to a second embodiment of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by the scope of the claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or light inputted from an exterior will be described in detail with reference to the accompanying drawings.

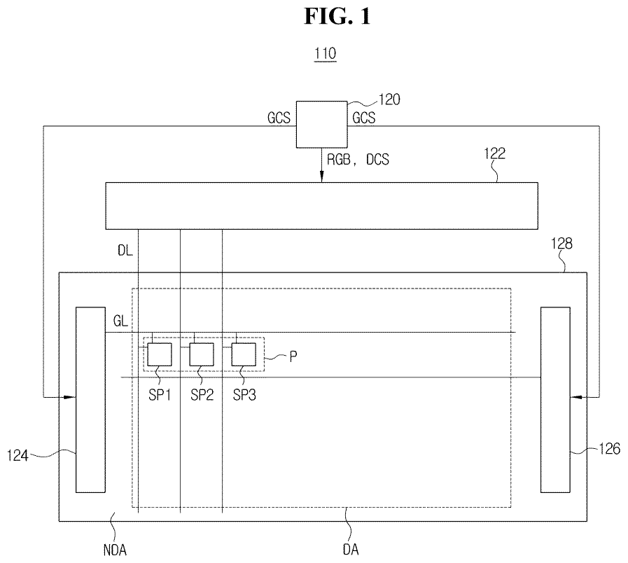

FIG. 1 is a view showing a display device according to a first embodiment of the present disclosure. Although the display device may be an organic light emitting diode (OLED) display device, it is not limited thereto. For example, the display device may be a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122 and transmits the gate control signal GCS to the first and second gate driving units 124 and 126.

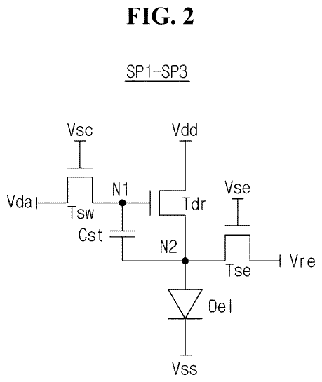

The data driving unit 122 generates a data signal (data voltage) Vda (of FIG. 2) using the image data RGB and the data control signal DCS transmitted from the timing controlling unit 120 and applies the data signal Vda to a data line DL of the display panel 128.

The first and second gate driving units 124 and 126 generate gate signals (gate voltages) Vsc and Vse (of FIG. 2) using the gate control signal GCS transmitted from the timing controlling unit 120 and applies the gate signals Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signals Vsc and Vse and the data signal Vda. For displaying an image, the display panel 128 includes a plurality of pixels P, a plurality of gate lines GL and a plurality of data lines DL in the display area DA.

Each of the plurality of pixels P includes first, second, and third subpixels SP1, SP2 and SP3, and the gate line GL and the data line DL cross each other to define the first, second and third subpixels SP1, SP2 and SP3. Each of the first, second and third subpixels SP1, SP2 and SP3 is connected to the gate line GL and the data line DL. For example, the first, second,, and third subpixels SP1, SP2 and SP3 may correspond to first, second and third colors, respectively, and the first, second and third colors may be red, green,, and blue colors, respectively.

Each of the first, second, and third subpixels SP1, SP2 and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to a first embodiment of the present disclosure.

In FIG. 2, each of the first, second, and third subpixels SP1, SP2 and SP3 of the display panel 128 of the display device 110 according to a first embodiment of the present disclosure includes a switching transistor Tsw, a driving transistor Tdr, a sensing transistor Tse, a storage capacitor Cst, and a light emitting diode Del.

Although each of the first, second, and third subpixels SP1, SP2 and SP3 has a 3T1C structure having three transistors and one storage capacitor in the first embodiment of FIG. 2, each of the first, second and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse may have a negative type in the first embodiment of FIG. 2, at least one of the switching transistor Tsw, the driving transistor Tdr and the sensing transistor Tse may have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N3 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vdata supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A cross-sectional structure of each subpixel SP1, SP2 and SP3 of the display panel 128 of the display device 110 will be illustrated with reference to a drawing.

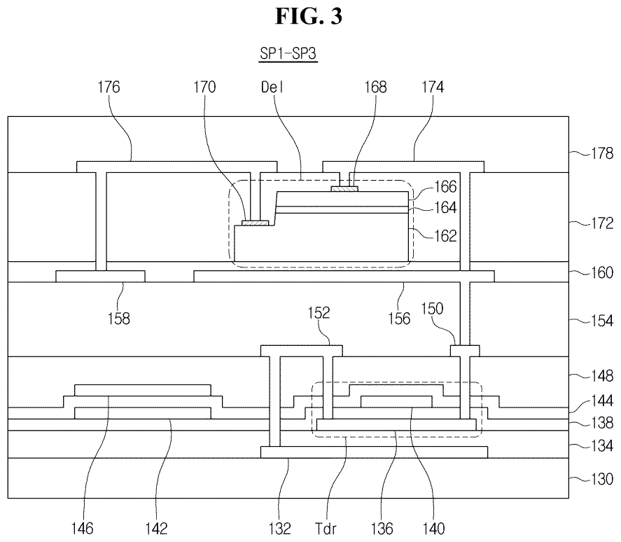

FIG. 3 is a cross-sectional view showing a subpixel of a display panel of a display device according to a first embodiment of the present disclosure.

In FIG. 3, a light shielding pattern 132 is disposed in each of the first, second and third subpixels SP1, SP2 and SP3 on a substrate 130, and a first buffer layer 134 is disposed on the light shielding pattern 132 over the entire substrate 130.

The light shielding pattern 132 may block a light incident from a lower portion of the substrate 130. For example, the light shielding pattern 132 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first buffer layer 134 may block moisture or oxygen permeating from an exterior. For example, the first buffer layer 134 may have a single layer or a multiple layer of an inorganic insulating material such as silicon oxide (SiO2) and silicon nitride (SiNx).

A semiconductor layer 136 is disposed on the first buffer layer 134 corresponding to the light shielding pattern 132, and a gate insulating layer 138 is disposed on the semiconductor layer 136 over the entire substrate 130.

The semiconductor layer 136 includes a channel region that is not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO2) and silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138, and the a first interlayer insulating layer 144 is disposed on the gate electrode 140 and the first capacitor electrode 142.

The gate electrode 140 and the first capacitor electrode 142 may have the same layer and the same material as each other. For example, the gate electrode 140 and the first capacitor electrode 142 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO2) and silicon nitride (SiNx).

A second capacitor electrode 146 is disposed on the first interlayer insulating layer 144 corresponding to the first capacitor electrode 142, and a second interlayer insulating layer 148 is disposed on the second capacitor electrode 146 over the entire substrate 130.

For example, the second capacitor electrode 146 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO2) and silicon nitride (SiNx).

The first capacitor electrode 142, the first interlayer insulating layer 144 and the second capacitor electrode 146 may constitute the storage capacitor Cst.

A source electrode 150 and a drain electrode 152 spaced apart from each other are disposed on the second interlayer insulating layer 148, and a first planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 may have the same layer and the same material as each other. For example, the source electrode 150 and the drain electrode 152 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A connecting electrode 156 is disposed on the first planarizing layer 154 corresponding to the source electrode 150, a power line 158 spaced apart from the connecting electrode 156 is disposed on the first planarizing layer 154, and an adhesive layer 160 is disposed on the connecting electrode 156 and the power line 158 over the entire substrate 130.

The connecting electrode 156 is connected to the source electrode 150 through a contact hole in the first planarizing layer 154, and the connecting electrode 156 and the power line 158 may have the same layer and the same material as each other.

For example, the connecting electrode 156 and the power line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the power line 158 may supply the low level signal Vss.

A first semiconductor layer 162 is disposed on the adhesive layer 160 corresponding to the connecting electrode 156, an active layer 164, a second semiconductor layer 166 and a first electrode 168 are sequentially disposed on a first side portion of the first semiconductor layer 162, and a second electrode 170 is disposed on a second side portion of the first semiconductor layer 162.

The first semiconductor layer 162 supplies an electron to the active layer 164, the second semiconductor layer 166 supplies a hole to the active layer 164, and the active layer 164 generates a light using an electron and a hole.

For example, the first semiconductor layer 162 may include negative type gallium nitride (n-GaN), the second semiconductor layer 166 may include positive type gallium nitride (p-GaN), and the active layer 164 may include a multi quantum well (MQW).

For example, the first electrode 168 may be a cathode, and the second electrode 170 may be an anode.

The first semiconductor layer 162, the active layer 164, the second semiconductor layer 166, the first electrode 168 and the second electrode 170 may constitute the light emitting diode Del (or light emitting diode chip).

A second planarizing layer 172 is disposed on the first and second electrodes 168 and 170 over the entire substrate 130, and first and second connecting lines 174 and 176 spaced apart from each other are disposed on the second planarizing layer 172 corresponding to the light emitting diode Del.

For example, the second planarizing layer 172 may have a single layer or a multiple layer of an organic insulating material such as photoacryl and benzocyclobutene (BCB).

The first connecting line 174 is connected to the connecting electrode 156 through a contact hole in the adhesive layer 160 and the second planarizing layer 172 and is connected to the first electrode 168 through a contact hole in the second planarizing layer 172.

The second connecting line 176 is connected to the power line 158 through a contact hole in the adhesive layer 160 and the second planarizing layer 172 and is connected to the second electrode 170 through a contact hole in the second planarizing layer 172.

For example, the first and second connecting lines 174 and 176 may include a transparent conductive material such as indium tin oxide (ITO) and indium zinc oxide (IZO).

An encapsulating layer 178 is disposed on the first and second connecting lines 174 and 176 over the entire substrate 130.

The encapsulating layer 178 prevents or at least reduces a permeation of a particle such as oxygen or moisture.

For example, the encapsulating layer 178 may have a single layer or a multiple layer of an inorganic insulating material such as silicon oxide (SiO2) and silicon nitride (SiNx).

Although the light emitting diode Del exemplarily has a lateral type in the first embodiment, the light emitting diode Del may have a vertical type in another embodiment.

The light emitting diode Del of the display device 110 may be attached to the substrate 130 through a self-assembly technology.

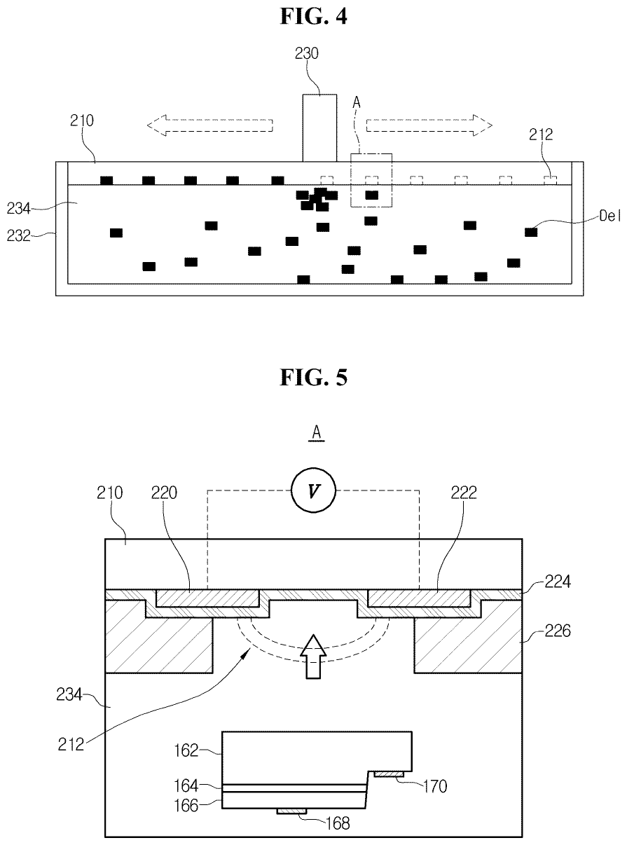

FIG. 4 is a view showing an assembly substrate of a light emitting diode of a display device according to a first embodiment of the present disclosure, and FIG. 5 is a magnified view of a portion A of FIG. 4 according to one embodiment.

In FIG. 4, an assembly substrate 210 having a plurality of assembly grooves 212 on a bottom surface thereof is disposed over a chamber 232, a magnetic rod 230 generating a magnetic field is disposed over the assembly substrate 210, and a fluid 234 including a plurality of light emitting diodes (LEDs) Del is disposed in the chamber 232.

The magnetic rod 230 may move along up, down, left and right directions and rotate, and the plurality of LEDs Del may be formed on a growth substrate and then be detached from the growth substrate.

For example, the fluid 234 may include a water such as a deionized water.

The plurality of LEDs Del moves toward the assembly substrate 210 in the fluid 234 by the magnetic field of the magnetic rod 230, and the LED Del may have a magnetic layer.

For example, the magnetic layer may include a metal having a magnetic property such as nickel (Ni) and may be disposed in one of first and second electrodes 168 and 170 of the LED Del.

In FIG. 5, first and second assembly electrodes 220 and 222 spaced apart from each other are disposed on a bottom surface of the assembly substrate 210, and an insulating layer 224 is disposed on the first and second assembly electrodes 220 and 222 over the entire assembly substrate 210.

For example, the first and second assembly electrodes 220 and 222 may include a transparent conductive material or a metallic material, and the insulating layer 224 may have a single layer or a multiple layer of an inorganic insulating material or an organic insulating material.

A sidewall 226 is disposed on the insulating layer 224 corresponding to the first and second assembly electrodes 220 and 222. The sidewall 226 partially overlaps the first and second assembly electrodes 220 and 222, and a space surrounded by the sidewall 226 constitutes the assembly groove 212.

When an alternating current (AC) voltage is applied to the first and second assembly electrodes 220 and 222, an electric field is generated between the first and second assembly electrodes 220 and 222, and the LED Del adjacent to the plurality of assembly grooves 212 among the plurality of LEDs Del in the fluid 234 may be assembled to the assembly groove 212 by a dielectric phoretic force due to the electric field generated between the first and second assembly electrodes 220 and 222.

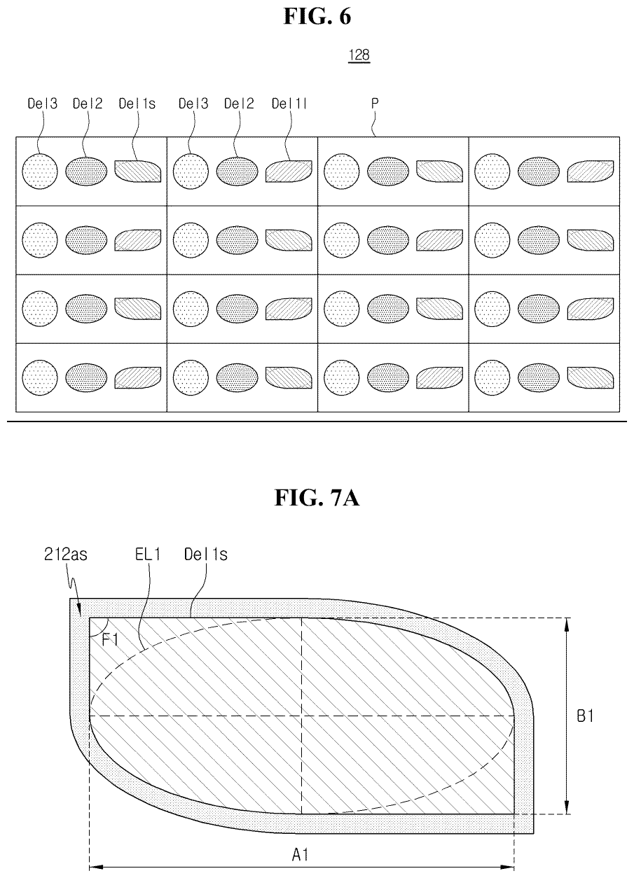

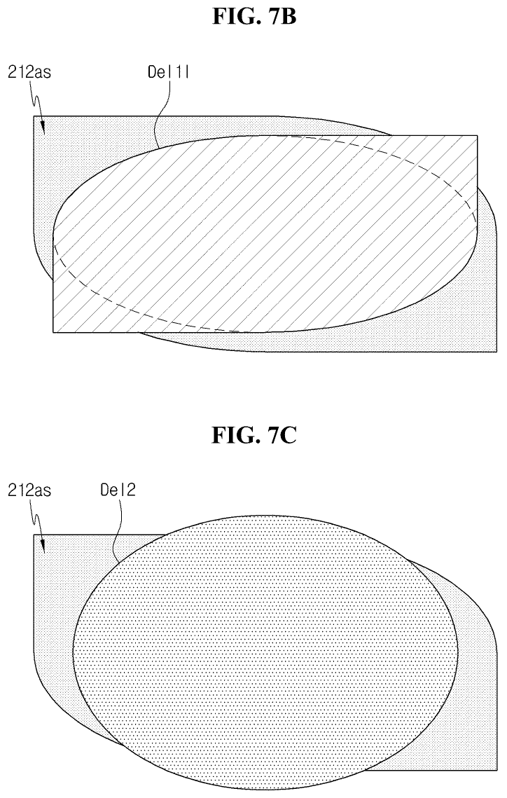

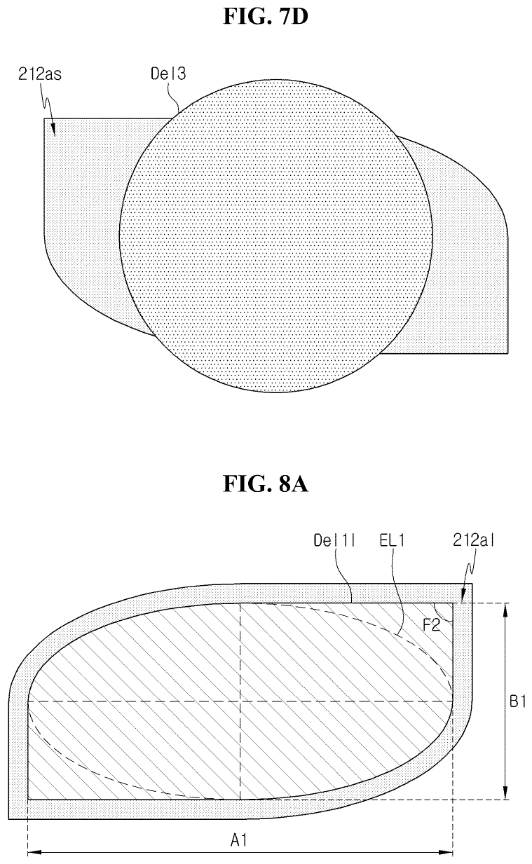

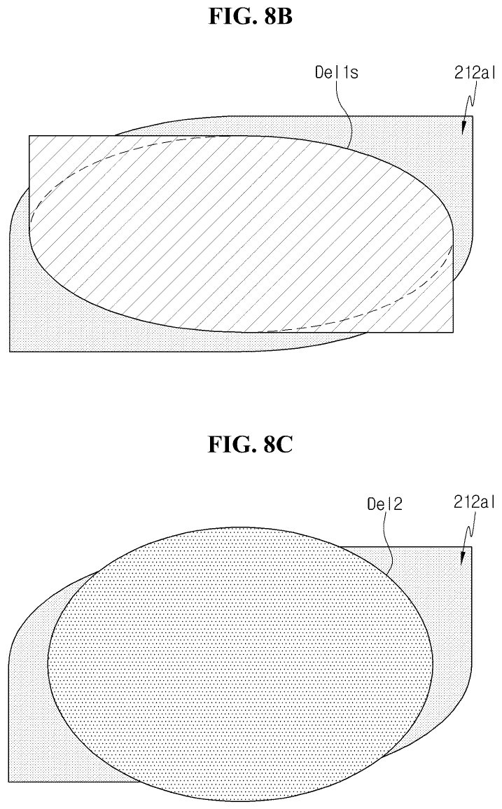

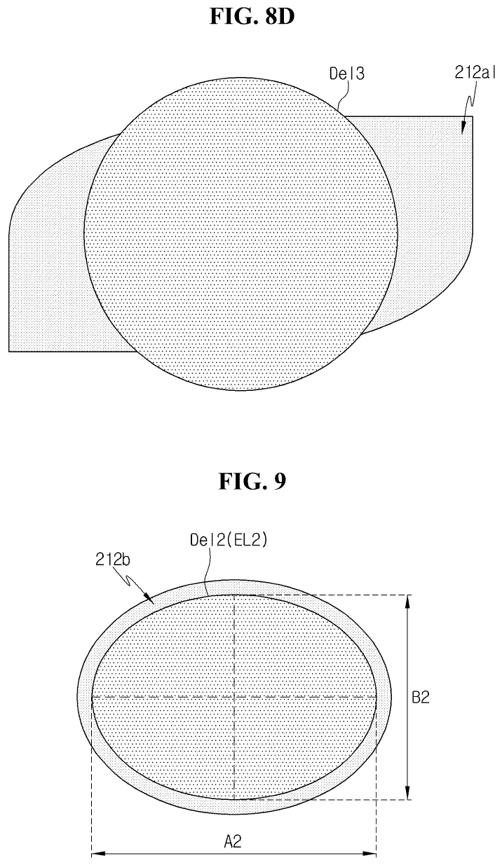

The plurality of LEDs Del include first, second and third LEDs Del1 (of FIG. 6A), Del2 (of FIG. 7A) and Del3 (of FIG. 8A) emitting first, second and third colored lights, respectively, and having first, second and third bottom patterns, respectively. The plurality of assembly grooves 212 include first, second and third assembly grooves 212a (of FIGS. 6A), 212b (of FIGS. 7A) and 212c (of FIG. 8A) corresponding to the first, second and third LEDs Del1, Del2 and Del3, respectively.

For example, the first, second and third colored lights may correspond to red, green and blue, respectively.

The first, second and third LEDs Del1, Del2 and Del3 and the first, second and third assembly grooves 212a, 212b and 212c of the assembly substrate 210 have different asymmetric polygonal shapes to have an exclusivity that a corresponding shape is selected.

When the first, second and third LEDs Del1, Del2 and Del3 are properly assembled to the first, second and third assembly grooves 212a, 212b and 212c, respectively, an electric force applied to the first, second and third LEDs Del1, Del2 and Del3 by the electric field of the first and second assembly electrodes 220 and 222 becomes greater than a magnetic force applied to the first, second and third LEDs Del1, Del2 and Del3 by the magnetic field of the magnetic rod 230 so that the first, second and third LEDs Del1, Del2 and Del3 cannot escape from and can be stably fixed to the first, second and third assembly grooves 212a, 212b and 212c, respectively.

When the first, second and third LEDs Del1, Del2 and Del3 are not properly assembled to the first, second and third assembly grooves 212a, 212b and 212c, respectively, the magnetic force applied to the first, second and third LEDs Del1, Del2 and Del3 by the magnetic field of the magnetic rod 230 becomes greater than the electric force applied to the first, second and third LEDs Del1, Del2 and Del3 by the electric field of the first and second assembly electrodes 220 and 222 so that the first, second and third LEDs Del1, Del2 and Del3 can escape from the first, second and third assembly grooves 212a, 212b and 212c, respectively. The first, second and third LEDs Del1, Del2 and Del3 having escaped from the first, second and third assembly grooves 212a, 212b and 212c may float in the fluid 234 till the first, second and third LEDs Del1, Del2 and Del3 are properly assembled to the corresponding first, second and third assembly grooves 212a, 212b and 212c, respectively.

When the plurality of LEDs Del are properly assembled to the plurality of assembly grooves 212 of the assembly substrate 210, the assembly substrate 210 is disposed on the adhesive layer 160 of the substrate 130 of the display panel 128, and the plurality of LEDs Del of the plurality of assembly grooves 212 are transferred and attached to the adhesive layer 160 of each subpixel SP1, SP2 and SP3.

In another embodiment, a transfer step may be omitted using the substrate 130 having the driving transistor Tdr as the assembly substrate 210.

Disposition and shapes of the plurality of grooves of the assembly substrate 210 and the plurality of LEDs Del will be illustrated with reference to drawings.

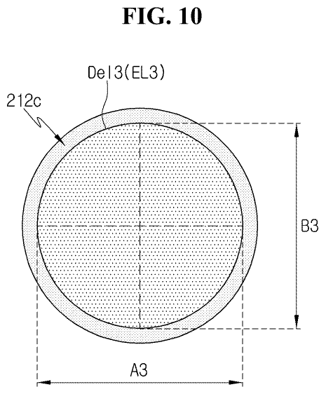

FIG. 6 is a view showing a display panel of a display device according to a first embodiment of the present disclosure. FIG. 7A is a view showing a first short wavelength assembly groove of an assembly substrate and a first short wavelength light emitting diode for a display device according to a first embodiment of the present disclosure, FIG. 7B is a view showing a first short wavelength assembly groove of an assembly substrate and a first long wavelength light emitting diode for a display device according to a first embodiment of the present disclosure, FIG. 7C is a view showing a first short wavelength assembly groove of an assembly substrate and a second light emitting diode for a display device according to a first embodiment of the present disclosure, and FIG. 7D is a view showing a first short wavelength assembly groove of an assembly substrate and a third light emitting diode for a display device according to a first embodiment of the present disclosure. FIG. 8A is a view showing a first long wavelength assembly groove of an assembly substrate and a first long wavelength light emitting diode for a display device according to a first embodiment of the present disclosure, FIG. 8B is a view showing a first long wavelength assembly groove of an assembly substrate and a first short wavelength light emitting diode for a display device according to a first embodiment of the present disclosure, FIG. 8C is a view showing a first long wavelength assembly groove of an assembly substrate and a second light emitting diode for a display device according to a first embodiment of the present disclosure, and FIG. 8D is a view showing a first long wavelength assembly groove of an assembly substrate and a third light emitting diode for a display device according to a first embodiment of the present disclosure. FIG. 9 is a view showing a second assembly groove of an assembly substrate and a second light emitting diode for a display device according to a first embodiment of the present disclosure, and FIG. 10 is a view showing a third assembly groove of an assembly substrate and a third light emitting diode for a display device according to a first embodiment of the present disclosure.

In FIG. 6, the display panel 128 of the display device 110 according to a first embodiment of the present disclosure includes a plurality of pixels P in a matrix shape along horizontal and vertical directions.

Each of the plurality of pixels P includes a first short wavelength LED Del1s corresponding to a first color, a second LED Del2 corresponding to a second color and a third LED Del3 corresponding to a third color, or includes a first long wavelength LED Del1l corresponding to a first color, a second LED Del2 corresponding to a second color and a third LED Del3 corresponding to a third color.

The first short wavelength LED Del1s has a short wavelength shorter than a first target wavelength as a dominant wavelength (Wd), and the first long wavelength LED Del1l has a long wavelength longer than the first target wavelength as a dominant wavelength. The second and third LEDs Del2 and Del3 have second and third target wavelengths, respectively, as a dominant wavelength.

For example, the first short wavelength LED Del1s may have the short wavelength of about 456 nm shorter than the first target wavelength of about 460 nm corresponding to a blue color as a dominant wavelength, and the first long wavelength LED Del1l may have the long wavelength of about 464 nm longer than the first target wavelength of about 460nm corresponding to a blue color as a dominant wavelength. The second LED Del2 may the second target wavelength of about 560nm corresponding to a green color as a dominant wavelength, and the third LED Del3 may have the third target wavelength of about 660 nm corresponding to a red color as a dominant wavelength.

The first long wavelength LED Del1l, the second LED Del2 and the third LED Del3 are disposed in a region adjacent to a pixel P including the first short wavelength LED Del1s, the second LED Del2 and the third LED Del3 along the horizontal and vertical directions.

As a result, the pixel P including the first short wavelength LED Del1s, the second LED Del2 and the third LED Del3 and the pixel P including the first long wavelength LED Del1l, the second LED Del2 and the third LED Del3 are alternately disposed with each other along the horizontal and vertical directions.

Accordingly, light of a short wavelength from the first short wavelength LED Del1s and a light of a long wavelength from the first long wavelength LED Del1l adjacent to the first short wavelength LED Del1s are mixed so that the plurality of pixels P can emit a light corresponding to the first target wavelength.

In FIG. 7A, the first short wavelength LED Del1s of the display device 110 according to a first embodiment of the present disclosure has a shape such that two opposite corners of a left upper portion and a right lower portion of a first elliptical shape EL1 expand as a polygonal shape, and a first short wavelength assembly groove 212as of the assembly substrate 210 where the first short wavelength LED Del1s is assembled has a shape corresponding to and greater than the first short wavelength LED Del1s.

The first short wavelength LED Del1s has a shape such that the left upper portion and the right lower portion of the first elliptical shape EL1 having a first long axis length A1 along the horizontal direction and a first short axis length B1 along the vertical direction expand as a polygonal shape of about 90 degree (a tangential line at a left vertex and a tangential line at an upper vertex of the first elliptical shape EL1 are connected to each other, a tangential line at a right vertex and a tangential line at a lower vertex of the first elliptical shape EL1 are connected to each other, and a first angle F1 between two tangential lines is about 90 degree). The first short wavelength assembly groove 212as has a shape greater than the first short wavelength LED Del1s such that the left upper portion and the right lower portion of the first elliptical shape EL1 expand as a polygonal shape.

In another embodiment, the first angle F1 may be smaller than or greater than about 90 degrees.

As a result, the first short wavelength LED Del1s is stably assembled to the first short wavelength assembly groove 212as.

Although not shown, a top surface of the first short wavelength LED Del1s may include a first surface over a step difference and having the first electrode 168 and a second surface under the step difference and having the second electrode 170 in a cross-sectional view.

In FIG. 8A, the first long wavelength LED Del1l of the display device 110 according to a first embodiment of the present disclosure has a shape such that two opposite corners of a left lower portion and a right upper portion of the first elliptical shape EL1 expand as a polygonal shape, and a first long wavelength assembly groove 212al of the assembly substrate 210 where the first long wavelength LED Del1l is assembled has a shape corresponding to and greater than the first long wavelength LED Del1l.

The first long wavelength LED Del1l has a shape such that the left lower portion and the right upper portion of the first elliptical shape EL1 having the first long axis length A1 along the horizontal direction and the first short axis length B1 along the vertical direction expand as polygonal shape of about 90 degree (a tangential line at a right vertex and a tangential line at an upper vertex of the first elliptical shape EL1 are connected to each other, a tangential line at a left vertex and a tangential line at a lower vertex of the first elliptical shape EL1 are connected to each other, and a second angle F2 between two tangential lines is about 90 degree). The first long wavelength assembly groove 212al has a shape greater than the first long wavelength LED Del1l such that the left lower portion and the right upper portion of the first elliptical shape EL1 expand as a polygonal shape.

In another embodiment, the second angle F2 may be smaller than or greater than about 90 degrees.

As a result, the first long wavelength LED Del1l is stably assembled to the first long wavelength assembly groove 212al.

Although not shown, a top surface of the first long wavelength LED Del1l may include a first surface over a step difference and having the first electrode 168 and a second surface under the step difference and having the second electrode 170 in a cross-sectional view.

In FIG. 9, the second LED Del2 of the display device 110 according to a first embodiment of the present disclosure has a second elliptical shape EL2, and a second assembly groove 212b of the assembly substrate 210 where the second LED Del2 is assembled has a shape corresponding to and greater than the second LED Del2.

The second LED Del2 has the second elliptical shape EL2 having a second long axis length A2 shorter than the first long axis length A1 along the horizontal direction and a second short axis length B2 longer than the first short axis length B1 along the vertical direction. The second assembly groove 212b has an elliptical shape greater than the second LED Del2 and similar to the second elliptical shape EL2.

As a result, the second LED Del2 is stably assembled to the second assembly groove 212b.

Although not shown, a top surface of the second LED Del2 may include a first surface over a step difference and having the first electrode 168 and a second surface under the step difference and having the second electrode 170 in a cross-sectional view.

In FIG. 10, the third LED Del3 of the display device 110 according to a first embodiment of the present disclosure has a third elliptical shape EL3, and a third assembly groove 212c of the assembly substrate 210 where the third LED Del3 is assembled has a shape corresponding to and greater than the third LED Del3.

The third LED Del3 has the third elliptical shape EL3 having a third long axis length A3 shorter than the second long axis length A2 along the horizontal direction and a third short axis length B3 longer than the second short axis length B2 along the vertical direction. The third assembly groove 212c has an elliptical shape greater than the third LED Del3 and similar to the third elliptical shape EL3.

For example, the third elliptical shape EL3 may be a circle where the third long axis length A3 and the third short axis length B3 are the same as each other.

As a result, the third LED Del3 is stably assembled to the third assembly groove 212c.

Although not shown, a top surface of the third LED Del3 may include a first surface over a step difference and having the first electrode 168 and a second surface under the step difference and having the second electrode 170 in a cross-sectional view.

In FIGS. 7B to 7D, even when a portion of each of the first long wavelength LED Del1l, the second LED Del2 and the third LED Del3 is inserted into the first short wavelength assembly groove 212as, at least one end portion of each of the first long wavelength LED Del1l, the second LED Del2 and the third LED Del3 escapes from the first short wavelength assembly groove 212as. As a result, each of the first long wavelength LED Del1l, the second LED Del2 and the third LED Del3 is not assembled to the first short wavelength assembly groove 212as to easily escape from the first short wavelength assembly groove 212as.

In FIGS. 8B to 8D, even when a portion of each of the first short wavelength LED Del1s, the second LED Del2 and the third LED Del3 is inserted into the first long wavelength assembly groove 212al, at least one end portion of each of the first short wavelength LED Del1s, the second LED Del2 and the third LED Del3 escapes from the first long wavelength assembly groove 212al. As a result, each of the first short wavelength LED Del1s, the second LED Del2 and the third LED Del3 is not assembled to the first long wavelength assembly groove 212al to easily escape from the first long wavelength assembly groove 212al.

The first short wavelength LED Del1s and the first long wavelength LED Del1l may be fabricated from a plurality of epitaxial wafers.

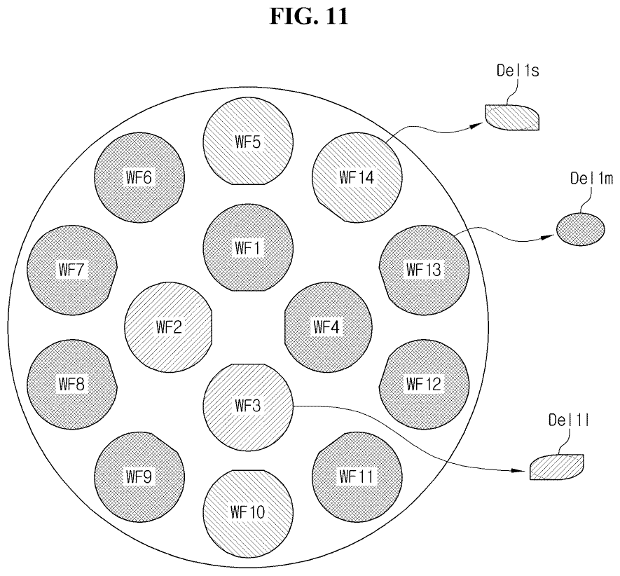

FIG. 11 is a view showing a plurality of epitaxial wavers for a light emitting diode of a display device according to a first embodiment of the present disclosure.

In FIG. 11, first to fourteenth epitaxial wafers WF1 to WF14 are formed by growing a crystal of gallium nitride (GaN) on a plurality of wafers through a metal organic chemical vapor deposition (MOCVD) method. Among the first to fourteenth epitaxial wafers WF1 to WF14, the first, fourth, sixth, seventh, eighth, ninth, eleventh, twelfth and thirteenth epitaxial wafers WF1, WF4, WF6, WF7, WF8, WF9, WF11, WF12 and WF13 have a middle wavelength corresponding to the first target wavelength as a dominant wavelength, the fifth and fourteenth epitaxial wafers WF5 and WF14 have a short wavelength shorter than the first target wavelength as a dominant wavelength, and the second, third and tenth epitaxial wafers WF2, WF3 and WF10 have a long wavelength longer than the first target wavelength as a dominant wavelength.

The dominant wavelength of the first to fourteenth epitaxial wafers WF1 to WF14 may be measured through a photoluminescence (PL) test where a light emitted from an active layer of gallium nitride (GaN) is detected after a light having an energy higher than a bandgap energy of the active layer of gallium nitride (GaN) is irradiated onto the active layer of gallium nitride (GaN).

A first middle wavelength LED Del1m having the middle wavelength corresponding to the first target wavelength as a dominant wavelength may be fabricated from the first, fourth, sixth, seventh, eighth, ninth, eleventh, twelfth and thirteenth epitaxial wafers WF1, WF4, WF6, WF7, WF8, WF9, WF11, WF12 and WF13 among the first to fourteenth epitaxial wafers WF1 to WF14. The first short wavelength LED Del1s having the short wavelength shorter than the first target wavelength as a dominant wavelength may be fabricated from the fifth and fourteenth epitaxial wafers WF5 and WF14 among the first to fourteenth epitaxial wafers WF1 to WF14, and the first long wavelength LED Del1l having the long wavelength longer than the first target wavelength as a dominant wavelength may be fabricated from the second, third and tenth epitaxial wafers WF2, WF3 and WF10 among the first to fourteenth epitaxial wafers WF1 to WF14.

A display device according to a comparison example includes only the first middle wavelength LED Del1m to prevent or at least reduce a color deviation, and the first short wavelength LED Del1s and the first long wavelength LED Del1l are discarded. The display device 110 according to a first embodiment of the present disclosure includes the first short wavelength LED Del1s and the first long wavelength LED Del1l as well as the first middle wavelength LED Del1m. As a result, the usage yield of a chip is improved.

In the display device 110 according to a first embodiment of the present disclosure, the first short wavelength LED Del1s is formed to have a shape that the two opposite corners of the left upper portion and the right lower portion of the first elliptical shape EL1 expand as a polygonal shape, and the first long wavelength LED Del1l is formed to have a shape that the two opposite corners of the left lower portion and the right upper portion of the first elliptical shape EL1 expand as a polygonal shape. The second LED Del2 is formed to have the second elliptical shape EL2 different from the first elliptical shape EL1, and the third LED Del3 is formed to have the third elliptical shape EL3 different from the first and second elliptical shapes EL1 and EL2. Further, the first short wavelength assembly groove 212as, the first long wavelength assembly groove 212al, the second assembly groove 212b and the third assembly groove 212c are formed to have shapes corresponding to the first short wavelength LED Del1s, the first long wavelength LED Del1l, the second LED Del2 and the third LED Del3, respectively. As a result, an exclusivity among the first short wavelength LED Del1s, the first long wavelength LED Del1l, the second LED Del2 and the third LED Del3 is improved, and a color mixture due to an abnormal assembly of the first short wavelength LED Del1s, the first long wavelength LED Del1l, the second LED Del2 and the third LED Del3 is prevented or at least reduced to obtain a high resolution.

Further, the first short wavelength LED Del1s having the short wavelength shorter than the first target wavelength as a dominant wavelength and the first long wavelength LED Del1l having the long wavelength longer than the first target wavelength as a dominant wavelength are disposed to be adjacent to each other along the horizontal and vertical directions. As a result, a color deviation is prevented or at least reduced, a usage yield of a chip increases, and a fabrication cost is reduced.

Although the first color of the first short wavelength LED Del1s and the first long wavelength LED Del1l, the second color of the second LED Del2 and the third color of the third LED Del3 exemplarily correspond to blue, green and red colors, respectively, in a first embodiment, the first, second and third colors may correspond to green, red and blue colors, respectively, or red, blue and green colors, respectively, in another embodiment. Alternatively, the first, second and third colors may correspond to different colors, respectively, in another embodiment.

Although the LED corresponding to the first color is exemplarily constituted by the first short wavelength LED Del1s and the first long wavelength LED Del1l in a first embodiment, the LED corresponding to the second color may be constituted by a second short wavelength LED having a shape that two opposite corners of a left upper portion and a right lower portion of a second elliptical shape EL2 expand as a polygonal shape and a second long wavelength LED having a shape that two opposite corners of a left lower portion and a right upper portion of the second elliptical shape EL2 expand as a polygonal shape in another embodiment. Alternatively, the LED corresponding to the third color may be constituted by a third short wavelength LED having a shape that two opposite corners of a left upper portion and a right lower portion of a third elliptical shape EL3 expand as a polygonal shape and a third long wavelength LED having a shape that two opposite corners of a left lower portion and a right upper portion of the third elliptical shape EL3 expand as a polygonal shape in another embodiment.

In another embodiment, the first short wavelength LED and the first long wavelength may have an area corresponding to the first middle wavelength LED.

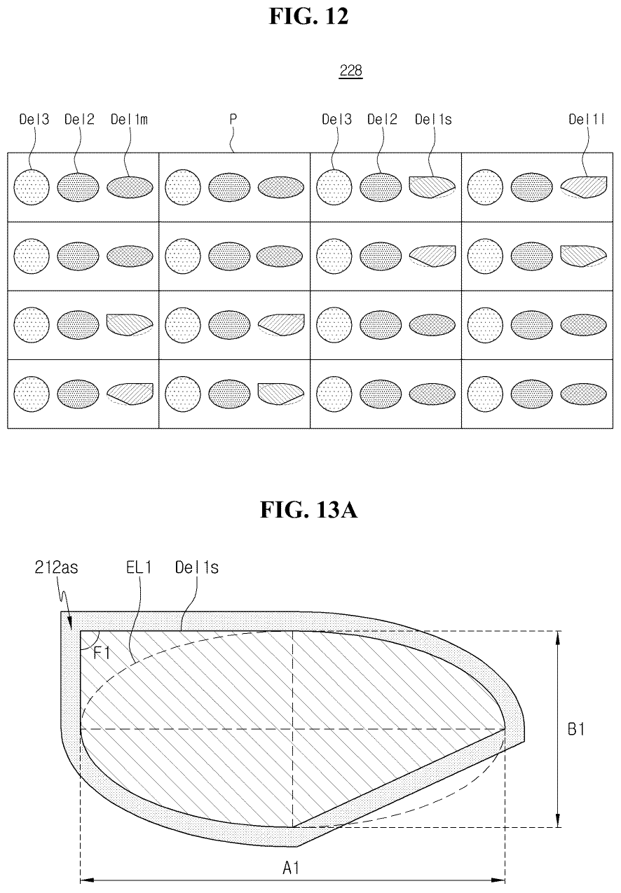

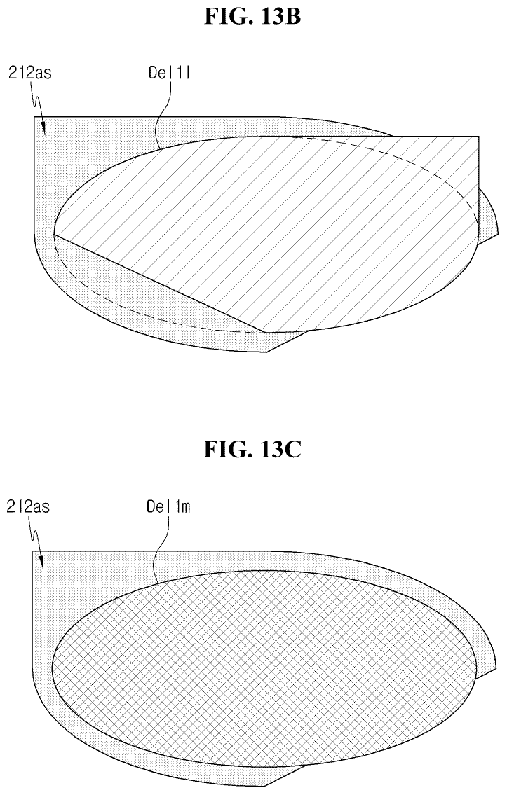

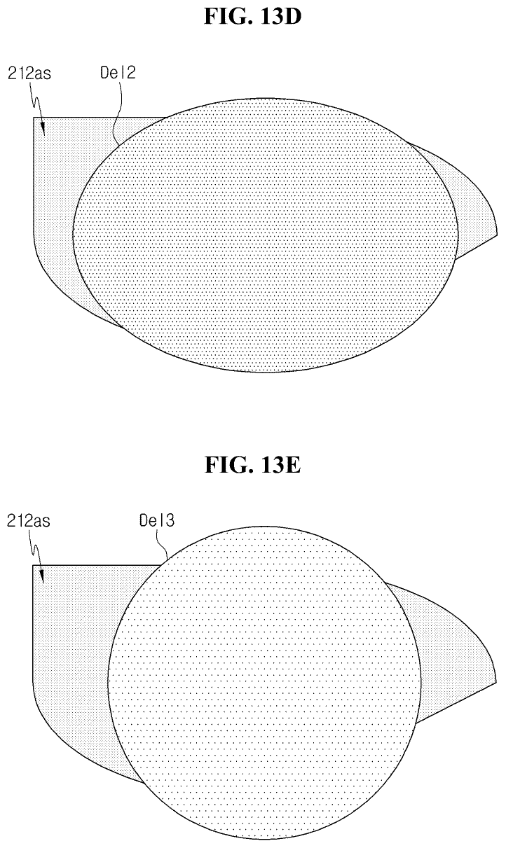

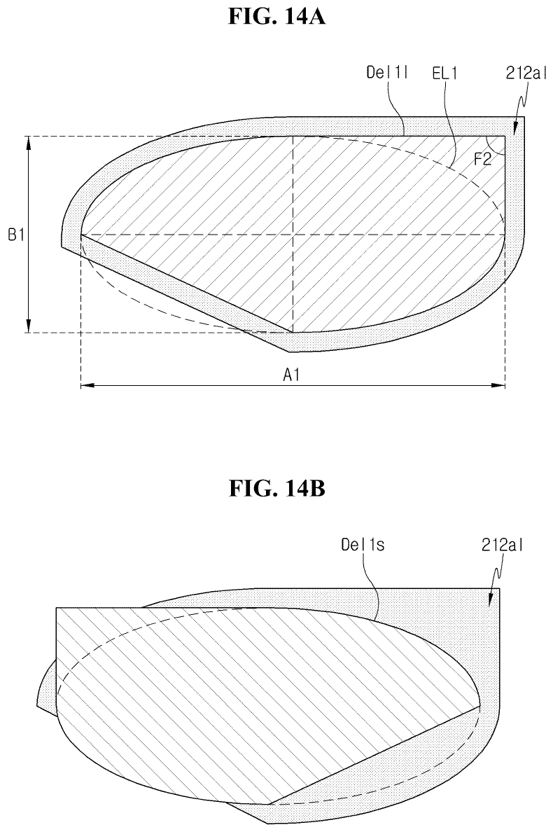

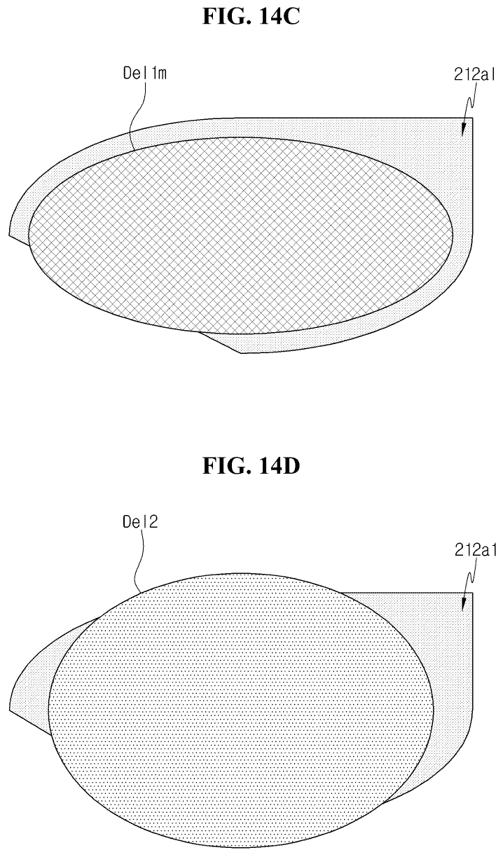

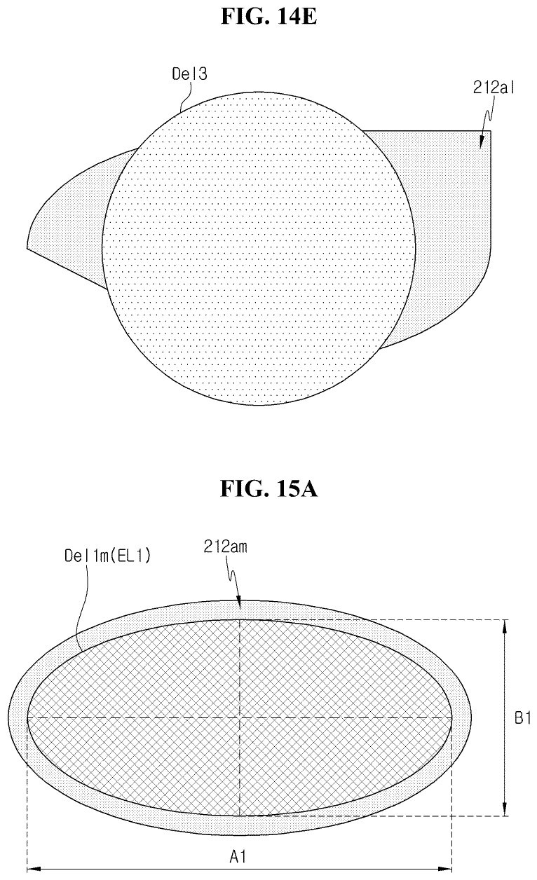

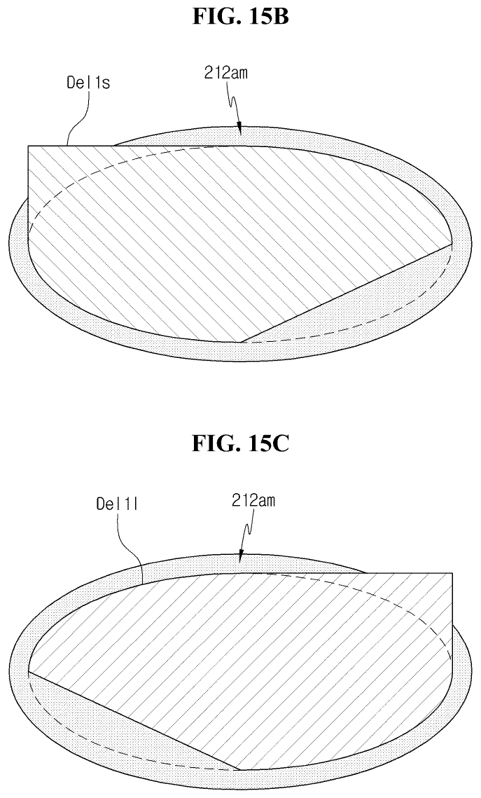

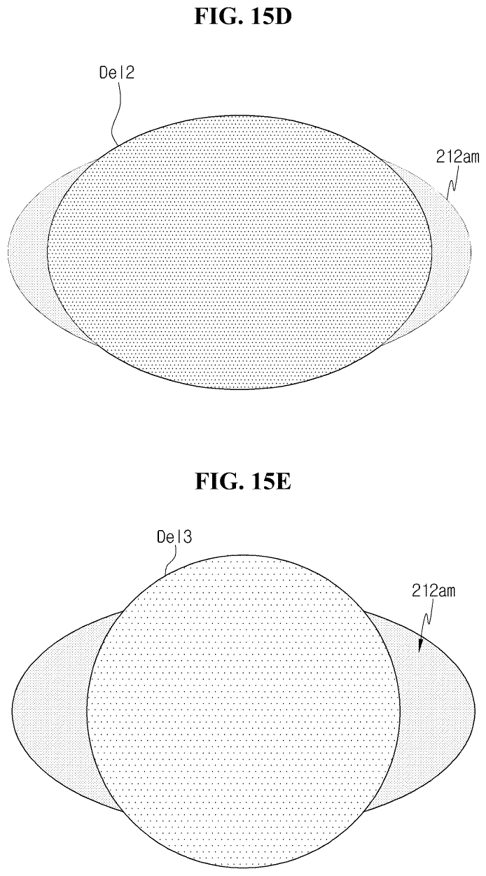

FIG. 12 is a view showing a display panel of a display device according to a second embodiment of the present disclosure. FIG. 13A is a view showing a first short wavelength assembly groove of an assembly substrate and a first short wavelength light emitting diode for a display device according to a second embodiment of the present disclosure, FIG. 13B is a view showing a first short wavelength assembly groove of an assembly substrate and a first long wavelength light emitting diode for a display device according to a second embodiment of the present disclosure, FIG. 13C is a view showing a first short wavelength assembly groove of an assembly substrate and a first middle wavelength light emitting diode for a display device according to a second embodiment of the present disclosure, FIG. 13D is a view showing a first short wavelength assembly groove of an assembly substrate and a second light emitting diode for a display device according to a second embodiment of the present disclosure, and FIG. 13E is a view showing a first short wavelength assembly groove of an assembly substrate and a third light emitting diode for a display device according to a second embodiment of the present disclosure. FIG. 14A is a view showing a first long wavelength assembly groove of an assembly substrate and a first long wavelength light emitting diode for a display device according to a second embodiment of the present disclosure, FIG. 14B is a view showing a first long wavelength assembly groove of an assembly substrate and a first short wavelength light emitting diode for a display device according to a second embodiment of the present disclosure, FIG. 14C is a view showing a first long wavelength assembly groove of an assembly substrate and a first middle wavelength light emitting diode for a display device according to a second embodiment of the present disclosure, FIG. 14D is a view showing a first long wavelength assembly groove of an assembly substrate and a second light emitting diode for a display device according to a second embodiment of the present disclosure, and FIG. 14E is a view showing a first long wavelength assembly groove of an assembly substrate and a third light emitting diode for a display device according to a second embodiment of the present disclosure. FIG. 15A is a view showing a first middle wavelength assembly groove of an assembly substrate and a first middle wavelength light emitting diode for a display device according to a second embodiment of the present disclosure, FIG. 15B is a view showing a first middle wavelength assembly groove of an assembly substrate and a first short wavelength light emitting diode for a display device according to a second embodiment of the present disclosure, FIG. 15C is a view showing a first middle wavelength assembly groove of an assembly substrate and a first long wavelength light emitting diode for a display device according to a second embodiment of the present disclosure, FIG. 15D is a view showing a first middle wavelength assembly groove of an assembly substrate and a second light emitting diode for a display device according to a second embodiment of the present disclosure, and FIG. 15E is a view showing a first middle wavelength assembly groove of an assembly substrate and a third light emitting diode for a display device according to a second embodiment of the present disclosure.

In FIG. 12, a display panel 228 of a display device according to a second embodiment of the present disclosure includes a plurality of pixels P in a matrix shape along horizontal and vertical directions.

Each of the plurality of pixels P includes a first middle wavelength LED Del1m corresponding to a first color, a second LED Del2 corresponding to a second color and a third LED Del3 corresponding to a third color, or includes a first short wavelength LED Del1s corresponding to a first color, a second LED Del2 corresponding to a second color and a third LED Del3 corresponding to a third color, or includes a first long wavelength LED Del1l corresponding to a first color, a second LED Del2 corresponding to a second color and a third LED Del3 corresponding to a third color.

The first middle wavelength LED Del1m has a middle wavelength corresponding to a first target wavelength as a dominant wavelength (Wd), the first short wavelength LED Del1s has a short wavelength shorter than the first target wavelength as a dominant wavelength, and the first long wavelength LED Del1l has a long wavelength longer than the first target wavelength as a dominant wavelength. The second and third LEDs Del2 and Del3 have second and third target wavelengths, respectively, as a dominant wavelength.

For example, the first middle wavelength LED Del1m may have the middle wavelength of about 460 nm of the first target wavelength corresponding to a blue color as a dominant wavelength, the first short wavelength LED Del1s may have the short wavelength of about 456 nm shorter than the first target wavelength of about 460 nm corresponding to a blue color as a dominant wavelength, and the first long wavelength LED Del1l may have the long wavelength of about 464 nm longer than the first target wavelength of about 460 nm corresponding to a blue color as a dominant wavelength. The second LED Del2 may the second target wavelength of about 560 nm corresponding to a green color as a dominant wavelength, and the third LED Del3 may have the third target wavelength of about 660 nm corresponding to a red color as a dominant wavelength.

Four pixels P each including the first middle wavelength LED Del1m, the second LED Del2 and the third LED Del3 are disposed adjacent to each other along horizontal and vertical directions. Two pixels P each including the first short wavelength LED Del1s, the second LED Del2 and the third LED Del3 and two pixels P including the first long wavelength LED Del1l, the second LED Del2 and the third LED Del3 are disposed adjacent to each other. The two pixels P including the first short wavelength LED Del1s are disposed at a left upper portion and a right lower portion of the four pixels P, and the two pixels P including the first long wavelength LED Del1l are disposed at a left lower portion and a right upper portion of the four pixels P.

As a result, the adjacent four pixels P each including the first middle wavelength LED Del1m, the second LED Del2 and the third LED Del3 and the adjacent four pixels P each including the first short wavelength LED Del1s, the second LED Del2 and the third LED Del3 or the first long wavelength LED Del1l, the second LED Del2 and the third LED Del3 are alternately disposed with each other along the horizontal and vertical directions.

Accordingly, a light of a short wavelength from the adjacent two first short wavelength LEDs Del1s and a light of a long wavelength from the adjacent two first long wavelength LEDs Del1l adjacent to the two first short wavelength LEDs Del1s are mixed to become a light similar to a light of a middle wavelength from the adjacent four first middle wavelength LEDs Del1m. As a result, the plurality of pixels P may emit a light corresponding to the first target wavelength.

In FIG. 13A, the first short wavelength LED Del1s of the display device according to a second embodiment of the present disclosure has a shape such that a corner of a left upper portion of a first elliptical shape EL1 expands as a polygonal shape and a corner of a right lower portion of the first elliptical shape EL1 contracts as a linear shape, and a first short wavelength assembly groove 212as of an assembly substrate where the first short wavelength LED Del1s is assembled has a shape corresponding to and greater than the first short wavelength LED Del1s.

The first short wavelength LED Del1s has a shape such that the left upper portion of the first elliptical shape EL1 having a first long axis length A1 along the horizontal direction and a first short axis length B1 along the vertical direction expands as a polygonal shape of about 90 degrees (a tangential line at a left vertex and a tangential line at an upper vertex of the first elliptical shape EL1 are connected to each other, and a first angle F1 between two tangential lines is about 90 degrees) and the right lower portion of the first elliptical shape EL1 contracts as a linear shape (a tangential line at a right vertex and a tangential line at a lower vertex of the first elliptical shape EL1 are connected to each other as a straight line). The first short wavelength assembly groove 212as has a shape greater than the first short wavelength LED Del1s such that the left upper portion of the first elliptical shape EL1 expands as a polygonal shape and the right lower portion of the first elliptical shape EL1 contracts as a linear shape.

In the first short wavelength LED Del1s, an area of the expanding left upper portion of the first elliptical shape EL1 and an area of the contracting right lower portion of the first elliptical shape EL1 may be similar to each other (substantially the same as each other), and an area of the first short wavelength LED Del1s and an area of the first elliptical shape EL1 may be similar to each other (substantially the same as each other).

In another embodiment, the first angle F1 may be smaller than or greater than about 90 degrees.

As a result, the first short wavelength LED Del1s is stably assembled to the first short wavelength assembly groove 212as.

Although not shown, a top surface of the first short wavelength LED Del1s may include a first surface over a step difference and having a first electrode and a second surface under the step difference and having a second electrode in a cross-sectional view.

In FIG. 14A, the first long wavelength LED Del1l of the display device according to a second embodiment of the present disclosure has a shape such that a corner of a left lower portion of the first elliptical shape EL1 contracts as a linear shape and a corner of a right upper portion of the first elliptical shape EL1 expands as a polygonal shape, and a first long wavelength assembly groove 212al of the assembly substrate where the first long wavelength LED Del1l is assembled has a shape corresponding to and greater than the first long wavelength LED Del1l.

The first long wavelength LED Del1l has a shape such that the left lower portion of the first elliptical shape EL1 having the first long axis length A1 along the horizontal direction and the first short axis length B1 along the vertical direction contracts as a linear shape (a left vertex and a lower vertex of the first elliptical shape EL1 are connected to each other as a straight line) and the right upper portion of the first elliptical shape EL1 expands as polygonal shape of about 90 degrees (a tangential line at a right vertex and a tangential line at an upper vertex of the first elliptical shape EL1 are connected to each other, and a second angle F2 between two tangential lines is about 90 degrees). The first long wavelength assembly groove 212al has a shape greater than the first long wavelength LED Del1l such that the left lower portion of the first elliptical shape EL1 contracts as a straight line and the right upper portion of the first elliptical shape EL1 expands as a polygonal shape.

In the first long wavelength LED Del1l, an area of the expanding right upper portion of the first elliptical shape EL1 and an area of the contracting left lower portion of the first elliptical shape EL1 may be similar to each other (substantially the same as each other), and an area of the first long wavelength LED Del1l and an area of the first elliptical shape EL1 may be similar to each other (substantially the same as each other).

In another embodiment, the second angle F2 may be smaller than or greater than about 90 degrees.

As a result, the first long wavelength LED Del1l is stably assembled to the first long wavelength assembly groove 212al.

Although not shown, a top surface of the first long wavelength LED Del1l may include a first surface over a step difference and having the first electrode and a second surface under the step difference and having the second electrode in a cross-sectional view.

In FIG. 15A, the first middle wavelength LED Del1m of the display device according to a second embodiment of the present disclosure has the first elliptical shape EL1, and a first middle wavelength assembly groove 212am of the assembly substrate where the first middle wavelength LED Del1m is assembled has a shape corresponding to and greater than the first middle wavelength LED Del1m.

The first middle wavelength LED Del1m has the first elliptical shape EL1 having the first long axis length A1 along the horizontal direction and the first short axis length B1 along the vertical direction, and the first middle wavelength assembly groove 212am has an elliptical shape greater than the first middle wavelength LED Del1m and similar to the first elliptical shape EL1.

Areas of the first middle wavelength LED Del1m, the first short wavelength LED Del1s and the first long wavelength LED Del1l may be similar to each other (substantially the same as each other).

As a result, the first middle wavelength LED Del1m is stably assembled to the first middle wavelength assembly groove 212am.

Although not shown, a top surface of the first middle wavelength LED Del1m may include a first surface over a step difference and having the first electrode and a second surface under the step difference and having the second electrode in a cross-sectional view.

Since the second LED Del2 and the third LED Del3 of the display device according to a second embodiment of the present disclosure have the same shape as the second LED Del2 and the third LED Del3 of the display device 110 according to a first embodiment of the present disclosure, illustration on the second LED Del2 and the third LED Del3 of the display device according to a second embodiment of the present disclosure is omitted.

In FIGS. 13B to 13E, even when the a portion of each of the first long wavelength LED Del1l, the first middle wavelength LED Del1m, the second LED Del2 and the third LED Del3 is inserted into the first short wavelength assembly groove 212as, at least one end portion of each of the first long wavelength LED Del1l, the first middle wavelength LED Del1m, the second LED Del2 and the third LED Del3 escapes from the first short wavelength assembly groove 212as. As a result, each of the first long wavelength LED Del1l, the first middle wavelength LED Del1m, the second LED Del2 and the third LED Del3 is not assembled to the first short wavelength assembly groove 212as to easily escape from the first short wavelength assembly groove 212as.

In FIGS. 14B to 14E, even when the a portion of each of the first short wavelength LED Del1s, the first middle wavelength LED Del1m, the second LED Del2 and the third LED Del3 is inserted into the first long wavelength assembly groove 212al, at least one end portion of each of the first short wavelength LED Del1s, the first middle wavelength LED Del1m, the second LED Del2 and the third LED Del3 escapes from the first long wavelength assembly groove 212al. As a result, each of the first short wavelength LED Del1s, the first middle wavelength LED Del1m, the second LED Del2 and the third LED Del3 is not assembled to the first long wavelength assembly groove 212al to easily escape from the first long wavelength assembly groove 212al.

In FIGS. 15B to 15E, even when the a portion of each of the first short wavelength LED Del1s, the first long wavelength LED Del1l, the second LED Del2 and the third LED Del3 is inserted into the first middle wavelength assembly groove 212am, at least one end portion of each of the first short wavelength LED Del1s, the first long wavelength LED Del1l, the second LED Del2 and the third LED Del3 escapes from the first middle wavelength assembly groove 212am. As a result, each of the first short wavelength LED Del1s, the first long wavelength LED Del1l, the second LED Del2 and the third LED Del3 is not assembled to the first middle wavelength assembly groove 212am to easily escape from the first middle wavelength assembly groove 212am.

In the display device according to a second embodiment of the present disclosure, the first short wavelength LED Del1s is formed to have a shape that the corner of the left upper portion of the first elliptical shape EL1 expands as a polygonal shape and the corner of the right lower portion of the first elliptical shape EL1 contracts as a linear shape, the first long wavelength LED Del1l is formed to have a shape that the corner of the left lower portion of the first elliptical shape EL1 contracts as a linear shape and the corner of the right upper portion of the first elliptical shape EL1 expands as a polygonal shape, and the first middle wavelength LED Del1m is formed to have the first elliptical shape EL1. The second LED Del2 is formed to have the second elliptical shape EL2 different from the first elliptical shape EL1, and the third LED Del3 is formed to have the third elliptical shape EL3 different from the first and second elliptical shapes EL1 and EL2. Further, the first short wavelength assembly groove 212as, the first long wavelength assembly groove 212al, the first middle wavelength assembly groove 212am, the second assembly groove 212b and the third assembly groove 212c are formed to have shapes corresponding to the first short wavelength LED Del1s, the first long wavelength LED Del1l, the first middle wavelength LED Del1m, the second LED Del2 and the third LED Del3, respectively. As a result, an exclusivity among the first short wavelength LED Del1s, the first long wavelength LED Del1l, the first middle wavelength LED Del1m, the second LED Del2 and the third LED Del3 is improved, and a color mixture due to an abnormal assembly of the first short wavelength LED Del1s, the first long wavelength LED Del1l, the first middle wavelength LED Del1m, the second LED Del2 and the third LED Del3 is prevented or at least reduced to obtain a high resolution.

Further, two of the first short wavelength LED Del1s having the short wavelength shorter than the first target wavelength as a dominant wavelength and the first long wavelength LED Del1l having the long wavelength longer than the first target wavelength as a dominant wavelength and two of the first middle wavelength LEDs Del1m each having the middle wavelength corresponding to the first target wavelength as a dominant wavelength are alternately disposed along the horizontal and vertical directions. As a result, a color deviation is prevented or at least reduced, a usage yield of a chip increases, and a fabrication cost is reduced.

Although the first color of the first short wavelength LED Del1s, the first long wavelength LED Del1l and the first middle wavelength LED Del1m, the second color of the second LED Del2 and the third color of the third LED Del3 exemplarily correspond to blue, green and red colors, respectively, in a second embodiment, the first, second and third colors may correspond to green, red and blue colors, respectively, or red, blue and green colors, respectively, in another embodiment. Alternatively, the first, second and third colors may correspond to different colors, respectively, in another embodiment.

Although the LED corresponding to the first color is exemplarily constituted by the first short wavelength LED Del1s, the first long wavelength LED Del1l and the first middle wavelength LED Del1m in a second embodiment, the LED corresponding to the second color may be constituted by a second short wavelength LED having a shape that a corner of a left upper portion of a second elliptical shape EL2 expands as a polygonal shape and a corner of a right lower portion of the second elliptical shape EL2 contracts as a linear shape, a second long wavelength LED having a shape that a corner of a right upper portion of the second elliptical shape EL2 expands as a polygonal shape and a corner of a left lower portion of the second elliptical shape EL2 contracts as a linear shape, and a second middle wavelength LED having the second elliptical shape in another embodiment. Alternatively, the LED corresponding to the third color may be constituted by a third short wavelength LED having a shape that a corner of a left upper portion of a third elliptical shape EL3 expands as a polygonal shape and a corner of a right lower portion of the third elliptical shape EL3 contracts as a linear shape, a third long wavelength LED having a shape that a corner of a right upper portion of the third elliptical shape EL3 expands as a polygonal shape and a corner of a left lower portion of the third elliptical shape EL3 contracts as a linear shape, and a third middle wavelength LED having the third elliptical shape in another embodiment.

In the display device according to first and second embodiments of the present disclosure, at least one of the first, second and third LEDs includes the middle wavelength LED emitting a light of the target wavelength, the short wavelength LED emitting a light of the wavelength shorter than the target wavelength by 20 nm and the long wavelength LED emitting a light of the wavelength longer than the target wavelength by 20 nm. The middle wavelength LED, the short wavelength LED and the long wavelength LED have different shapes having an exclusivity, and the short wavelength LED and the long wavelength LED are disposed adjacent to each other along the horizontal and vertical directions. Since the LED corresponding to the wavelength shorter than the target wavelength and the LED corresponding to the wavelength longer than the target wavelength are disposed adjacent to each other, the color deviation due to individual disposition is prevented or at least reduced.

As a result, the exclusivity between the LEDs in the display device is improved, and the color mixture due to the abnormal assembly of the first, second and third LEDs is prevented or at least reduced. Since all of the middle wavelength LED, the short wavelength LED and the long wavelength LED generated from the fabrication process of the LED chip are sued for the display device, the usage yield of a chip increases, and the fabrication cost is reduced.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a display panel;
a plurality of gate lines and a plurality of data lines in the display panel, the plurality of gate lines and the plurality of data lines crossing each other and define a first subpixel, a second subpixel, and a third subpixel;
a transistor in each of the first subpixel, the second subpixel, and the third subpixel and connected to the plurality of gate lines and the plurality of data lines; and
a first light emitting diode, a second light emitting diode, and a third light emitting diode in the first subpixel, the second subpixel, and the third subpixel, respectively, and connected to the transistor,
wherein the first light emitting diode includes a first short wavelength light emitting diode and a first long wavelength light emitting diode having shapes that are different from each other, and
wherein the first short wavelength light emitting diode and the first long wavelength light emitting diode are alternately disposed along a horizontal direction and a vertical direction.

2. The display device of claim 1, wherein the first short wavelength light emitting diode and the first long wavelength light emitting diode have corners of different polygonal shapes.

3. The display device of claim 1, wherein a dominant wavelength of the first short wavelength light emitting diode is shorter than a dominant wavelength of the first long wavelength light emitting diode.

4. The display device of claim 1, wherein the first short wavelength light emitting diode has a shape such that two corners of a left upper portion and a right lower portion of a first elliptical shape expand as a polygonal shape, and
wherein the first long wavelength light emitting diode has a shape such that two corners of a left lower portion and a right upper portion of the first elliptical shape expand as a polygonal shape.

5. The display device of claim 4, wherein the second light emitting diode has a second elliptical shape that is different from the first elliptical shape, and
wherein the third light emitting diode has a third elliptical shape that is different from the first elliptical shape and the second elliptical shape.

6. The display device of claim 5, wherein the first elliptical shape has a first long axis length and a first short axis length,
wherein the second elliptical shape has a second long axis length that is smaller than the first long axis length and a second short axis length greater than the first short axis length, and
wherein the third elliptical shape has a third long axis length that is smaller than the second long axis length and a third short axis length that is greater than the second short axis length.

7. The display device of claim 1, wherein the first light emitting diode further includes a first middle wavelength light emitting diode having a shape that is different from a shape of the first short wavelength light emitting diode and the first long wavelength light emitting diode, and
wherein two of the first middle wavelength light emitting diodes and two of the first short wavelength light emitting diode and the first long wavelength light emitting diode are alternately disposed along the horizontal direction and the vertical direction.

8. The display device of claim 7, wherein the first middle wavelength light emitting diode, the first short wavelength light emitting diode, and the first long wavelength light emitting diode have shapes that are different from each other.

9. The display device of claim 7, wherein a dominant wavelength of the first middle wavelength light emitting diode is longer than a dominant wavelength of the first short wavelength light emitting diode and is shorter than a dominant wavelength of the first long wavelength light emitting diode.

10. The display device of claim 7, wherein the first short wavelength light emitting diode has a shape such that a corner of a left upper portion of a first elliptical shape expands as a polygonal shape and a corner of a right lower portion of the first elliptical shape contracts as a linear shape,
wherein the first long wavelength light emitting diode has a shape such that a corner of a right upper portion of the first elliptical shape expands as a polygonal shape and a corner of a left lower portion of the first elliptical shape contracts as a linear shape, and
wherein the first middle wavelength light emitting diode has the first elliptical shape.

11. The display device of claim 10, wherein the corner of the left upper portion of the first short wavelength light emitting diode is formed by a connection of a tangential line at a left vertex of the first elliptical shape and a tangential line at an upper vertex of the first elliptical shape, and the corner of the right lower portion of the first short wavelength light emitting diode is formed by a connection of a right vertex of the first elliptical shape and a lower vertex of the first elliptical shape through a straight line, and
wherein the corner of the right upper portion of the first long wavelength light emitting diode is formed by a connection of a tangential line at a right vertex of the first elliptical shape and a tangential line at an upper vertex of the first elliptical shape, and the corner of the left lower portion of the first long wavelength light emitting diode is formed by a connection of a left vertex of the first elliptical shape and a lower vertex of the first elliptical shape through a straight line.

12. The display device of claim 1, wherein each of the first light emitting diode, the second light emitting diode, and the third light emitting diode comprises:
a first semiconductor layer;
an active layer on a first side portion of the first semiconductor layer;
a second semiconductor layer on the active layer;
a first electrode on the second semiconductor layer; and
a second electrode on a second side portion of the first semiconductor layer.
